(19) United States
(12) Patent Application Publication
(10) Pub. No.: US 2025/0115996 A1
(43) Pub. Date: Apr. 10, 2025

(54) Substrate Processing Method, Method of Manufacturing Semiconductor Device, Non-transitory Computer-readable Recording Medium and Substrate Processing Apparatus

(71) Applicant: Kokusai Electric Corporation, Tokyo (JP)

(72) Inventors: Kaoru YAMAMOTO, Toyama (JP); Naofumi OHASHI, Toyama (JP)

(21) Appl. No.: 18/905,713

(22) Filed: Oct. 3, 2024

(30) Foreign Application Priority Data
Oct. 5, 2023 (JP) 2023-173803

(51) Int. Cl. C23C 16/455

(52) U.S. Cl. CPC C23C 16/45557; C23C 16/4557

(57) ABSTRACT

According to the present disclosure, it is possible to suppress a change in a state of a gas. There is provided a technique that includes: (a) adjusting at least one selected from the group of a pressure and a temperature of a buffer space in a buffer chamber when the temperature of the buffer space is out of a pre-set temperature range or the pressure of the buffer space is out of a pre-set pressure range; and (b) processing a substrate by supplying a gas via the buffer chamber to a process chamber in which the substrate is processed.

### CROSS REFERENCE TO RELATED APPLICATIONS

This non-provisional U.S. patent application is based on and claims priority under 35 U.S.C. § 119(a)-(d) from Japanese Patent Application No. 2023-173803 filed on Oct. 5, 2023, in the Japanese Patent Office, the entire contents of which are hereby incorporated by reference.

### TECHNICAL FIELD

The present disclosure relates to a substrate processing method, a method of manufacturing a semiconductor device, a non-transitory computer-readable recording medium and a substrate processing apparatus.

### BACKGROUND

According to some related arts, as a part of a manufacturing process of a semiconductor device, a film on a substrate may be processed by supplying a process gas to the substrate in a process vessel.

In a substrate processing apparatus configured to perform such a process described above, an adiabatic expansion of a gas (such as the process gas supplied through a supply pipe) may occur due to widening of a space in a buffer chamber. In such a case, a temperature of the gas may be lowered. As a result, particles may be generated in a process space when the gas supplied through the supply pipe is liquefied in the buffer chamber.

### SUMMARY

According to the present disclosure, there is provided a technique capable of suppressing a change in a state of a gas.

According to an embodiment of the present disclosure, there is provided a technique that includes: (a) adjusting at least one selected from the group of a pressure and a temperature of a buffer space in a buffer chamber when the temperature of the buffer space is out of a pre-set temperature range or the pressure of the buffer space is out of a pre-set pressure range; and (b) processing a substrate by supplying a gas via the buffer chamber to a process chamber in which the substrate is processed.

### BRIEF DESCRIPTION OF THE DRAWINGS

FIG. 1 is a diagram schematically illustrating a vertical cross-section of a substrate processing apparatus according to one or more embodiments of the technique of the present disclosure.

FIG. 2 is a block diagram schematically illustrating a configuration of a controller and related components of the substrate processing apparatus according to the embodiments of the present disclosure.

FIG. 3 is a flow chart schematically illustrating a substrate processing according to the embodiments of the present disclosure.

### DETAILED DESCRIPTION

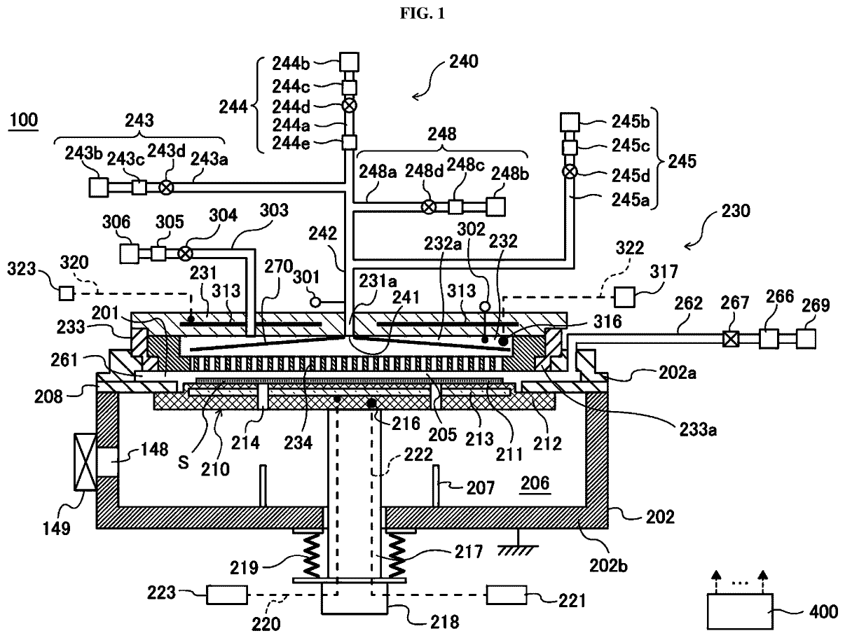

Hereinafter, one or more embodiments (also simply referred to as “embodiments”) of the technique of the present disclosure will be described in detail mainly with reference to FIGS. 1 to 3. The drawings used in the following description are all schematic. For example, a relationship between dimensions of each component and a ratio of each component shown in the drawing may not always match the actual ones. Further, even between the drawings, the relationship between the dimensions of each component and the ratio of each component may not always match.

### First Embodiment

Hereinafter, a first embodiment of the technique of the present disclosure will be described.

### (1) Configuration of Substrate Processing Apparatus

FIG. 1 is a diagram schematically illustrating a vertical cross-section of a substrate processing apparatus 100 configured to perform a method of manufacturing a semiconductor device. The substrate processing apparatus 100 includes a vessel 202. For example, the vessel 202 is made of a metal material such as aluminum (Al) and stainless steel (SUS). A process space 205 in which a substrate S such as a silicon wafer is processed and a transfer space 206 through which the substrate S is transferred into or out of the process space 205 are provided in the vessel 202. The vessel 202 is constituted by an upper vessel 202a and a lower vessel 202b. A partition plate 208 is provided between the upper vessel 202a and the lower vessel 202b. A structure defining the process space 205 may also be referred to as a “process chamber 201.” According to the present embodiment, the process chamber 201 is constituted mainly by a dispersion plate 234 and a substrate mounting table 212, which will be described later.

A substrate loading/unloading port 148 is provided adjacent to a gate valve 149 at a side surface of the lower vessel 202b. The substrate S is moved (transferred) between the transfer space 206 and a transfer chamber (not shown) through the substrate loading/unloading port 148. A plurality of lift pins 207 are provided at a bottom of the lower vessel 202b. In addition, the lower vessel 202b is electrically grounded.

A substrate support 210 configured to support the substrate S is provided in the process space 205. The substrate support 210 mainly includes: the substrate mounting table 212 provided with a substrate placing surface 211 on a surface thereof, where the substrate S is placed on the substrate placing surface 211; and a heater 213 serving as a first heating structure (first heater) provided in the substrate mounting table 212. The heater 213 may also be referred to as a “substrate mounting table heater.” Through-holes 214 through which the lift pins 207 penetrate are provided at positions of the substrate mounting table 212 corresponding to the lift pins 207.

A temperature measurer (which is a temperature measuring structure) 216 configured to measure a temperature of the heater 213 is provided in the substrate mounting table 212. The temperature measurer 216 is connected to a temperature meter 221 via a wiring 222.

A wiring 220 through which the electric power is supplied (applied) is connected to the heater 213. The heater 213 is connected to a heater controller 223 via the wiring 220.

The substrate mounting table 212 is supported by a shaft 217. The shaft 217 penetrates the bottom of the vessel 202, and is connected to an elevator 218 at an outside of the vessel 202.

The substrate mounting table 212 is configured such that the substrate S placed on the substrate placing surface 211 can be elevated or lowered by operating the elevator 218 to elevate or lower the shaft 217 and the substrate mounting table 212. In addition, a bellows 219 covers a periphery of a lower end of the shaft 217 to maintain the process space 205 airtight.

When the substrate S is transferred, the substrate mounting table 212 is lowered until the substrate placing surface 211 faces the substrate loading/unloading port 148, that is, until a transfer position of the substrate S is reached. When the substrate S is processed, the substrate mounting table 212 is elevated until the substrate S reaches a processing position (also referred to as a substrate processing position) in the process space 205 as shown FIG. 1.

A shower head 230 serving as a gas dispersion structure is provided in an upper portion (upstream side) of the process space 205. A lid 231 of the shower head 230 is provided with a through-hole 231a. The through-hole 231a is configured to communicate with a common gas supply pipe 242 described later. A buffer chamber 232a provided with a buffer space 232 therein is provided in the shower head 230. A gas such as a process gas is supplied to the process space 205 through the buffer space 232. The shower head 230 will be described in detail later.

A gas guide 270 is provided in the buffer space 232. For example, the gas guide 270 is of a conic shape around a gas introduction port 241, and a diameter of the gas guide 270 increases along a radial direction of the substrate S. The gas guide 270 is configured such that a lower end of an edge of the gas guide 270 is located outside an edge (end) of the substrate S. The gas guide 270 is configured to efficiently guide the gas supplied thereto in a direction of the dispersion plate 234 described later.

The upper vessel 202a is provided with a flange. A support block 233 is placed on and fixed to the flange. The support block 233 includes a flange 233a. The dispersion plate 234 provided with a plurality of gas supply holes is placed on and fixed to the flange 233a. Further, the lid 231 is fixed to an upper surface of the support block 233.

Subsequently, a gas supplier (which is a gas supply structure or a gas supply system) 240 will be described. A first gas supply pipe 243a, a second gas supply pipe 244a, a third gas supply pipe 245a and a fourth gas supply pipe 248a are connected to the common gas supply pipe 242.

A first gas supply source 243b, a mass flow controller (MFC) 243c serving as a flow rate controller (flow rate control structure) and a valve 243d serving as an opening/closing valve are sequentially provided at the first gas supply pipe 243a in this order from an upstream side toward a downstream side of the first gas supply pipe 243a in a gas flow direction.

The first gas supply source 243b is a source of a first gas (also referred to as a “first element-containing gas”) containing a first element. The first element-containing gas serves as a source gas, that is, one of process gases.

For example, a first gas supplier (which is a first gas supply structure or a first gas supply system) 243 is constituted mainly by the first gas supply pipe 243a, the MFC 243c and the valve 243d. The first gas supplier 243 may further include the first gas supply source 243b.

A second gas supply source 244b, a mass flow controller (MFC) 244c and a valve 244d are sequentially provided at the second gas supply pipe 244a in this order from an upstream side toward a downstream side of the second gas supply pipe 244a in the gas flow direction.

The second gas supply source 244b is a source of a second gas (also referred to as a “second element-containing gas”) containing a second element. The second element-containing gas is one of the process gases. For example, the second element-containing gas may serve as a reactive gas or a modifying gas.

When the substrate S is processed with the second gas in a plasma state, a plasma generator (also referred to as a “remote plasma unit”) 244e may be provided at the second gas supply pipe 244a.

A second gas supplier (which is a second gas supply structure or a second gas supply system) 244 is constituted mainly by the second gas supply pipe 244a, the MFC 244c and the valve 244d. The second gas supplier 244 may also be referred to as a “reactive gas supplier” (which is a reactive gas supply structure or a reactive gas supply system). The second gas supplier 244 may further include the plasma generator 244e. In addition, the second gas supplier 244 may further include the second gas supply source 244b.

A third gas supply source 245b, a mass flow controller (MFC) 245c and a valve 245d are sequentially provided at the third gas supply pipe 245a in this order from an upstream side toward a downstream side of the third gas supply pipe 245a in the gas flow direction.

The third gas supply source 245b is a source of an inert gas.

A third gas supplier (which is a third gas supply structure or a third gas supply system) 245 is constituted mainly by the third gas supply pipe 245a, the MFC 245c and the valve 245d. The third gas supplier 245 may further include the third gas supply source 245b.

The inert gas supplied from the third gas supply source 245b serves as a purge gas for purging the gas remaining in the vessel 202 or the shower head 230 in a substrate processing described later.

A fourth gas supply source 248b, a mass flow controller (MFC) 248c and a valve 248d are sequentially provided at the fourth gas supply pipe 248a in this order from an upstream side toward a downstream side of the fourth gas supply pipe 248a in the gas flow direction.

The fourth gas supply source 248b is a source of a cleaning gas.

A fourth gas supplier (which is a fourth gas supply structure or a fourth gas supply system) 248 is constituted mainly by the fourth gas supply pipe 248a, the MFC 248c and the valve 248d. The fourth gas supplier 248 may further include the fourth gas supply source 248b.

The cleaning gas supplied from the fourth gas supply source 248b is converted into a plasma state when cleaning the process chamber 201 or the shower head 230. It is possible to remove by-products remaining in the vessel 202 or the shower head 230 by supplying the cleaning gas in the plasma state.

An exhaust pipe 262 communicates with the process space 205 via an exhaust buffer structure 261. The exhaust buffer structure 261 is of a circumferential shape so as to surround an outer periphery of the substrate S. According to the present embodiment, the exhaust buffer structure 261 is provided between the partition plate 208 and the upper vessel 202a.

The exhaust pipe 262 is connected to the upper vessel 202a on an upper portion of the exhaust buffer structure 261 such that the exhaust pipe 262 communicates with the process space 205 via the exhaust buffer structure 261. An APC (Automatic Pressure Controller) 266 is provided at the exhaust pipe 262. The APC 266 serves as a pressure controller capable of controlling an inner pressure of the process space 205 to a predetermined pressure. The APC 266 includes a valve structure (not shown) whose opening degree can be adjusted. The APC 266 is configured to adjust a conductance of the exhaust pipe 262 in accordance with an instruction from a controller 400 described later.

A valve 267 is provided at the exhaust pipe 262 on an upstream side of the APC 266. Further, a vacuum pump 269 is provided at a downstream side of the exhaust pipe 262. The vacuum pump 269 is configured to exhaust an inner atmosphere of the process space 205 via the exhaust pipe 262. The exhaust pipe 262, the valve 267 and the APC 266 may be collectively referred to as a first exhauster (which is a first exhaust structure or a first exhaust system). The first exhauster may further include the vacuum pump 269.

Subsequently, a structure of the shower head 230 will be described in detail. A heater 313 serving as a second heating structure (second heater) is provided in the lid 231. The heater 313 may also be referred to as a “shower head heater.”

A wiring 320 through which the electric power is supplied (applied) is connected to the heater 313. The heater 313 is connected to a heater controller 323 via the wiring 320. The heater 313 is configured to heat the buffer space 232 in the shower head 230 in accordance with an instruction from the heater controller 323.

A pressure meter (which is a pressure measuring structure) 301 serving as a first pressure meter capable of measuring an inner pressure of the common gas supply pipe 242 is provided at the common gas supply pipe 242. Further, a pressure meter 302 serving as a second pressure meter capable of measuring a pressure of the buffer space 232 is provided in the buffer space 232. A temperature measurer 316 capable of measuring a temperature of the buffer space 232 is provided at the buffer space 232. The temperature measurer 316 is connected to a temperature meter 317 via a wiring 322.

An exhaust pipe 303 is provided to communicate with the buffer space 232. The exhaust pipe 303 is connected to the lid 231 on an upper portion of the buffer space 232. A valve 304, an APC (Automatic Pressure Controller) 305 and a vacuum pump 306 are sequentially provided at the exhaust pipe 303 in this order from an upstream side toward a downstream side of exhaust pipe 303 in the gas flow direction. The APC 305 serves as a pressure regulator (which is a pressure adjusting structure or a pressure controller) capable of controlling the pressure of the buffer space 232 to a predetermined pressure. The vacuum pump 306 is configured to exhaust an inner atmosphere of the buffer space 232 via the exhaust pipe 303. The exhaust pipe 303, the valve 304 and the APC 305 may be collectively referred to as a second exhauster (which is a second exhaust structure or a second exhaust system). The second exhauster may further include the vacuum pump 306.

The APC 305 includes a valve structure (not shown) whose opening degree can be adjusted. The APC 305 is configured to adjust a conductance of the exhaust pipe 303 in accordance with an instruction from the controller 400 described later.

### Controller

The substrate processing apparatus 100 is provided with the controller 400 serving as a control structure (or a control apparatus) configured to control operations of components constituting the substrate processing apparatus 100.

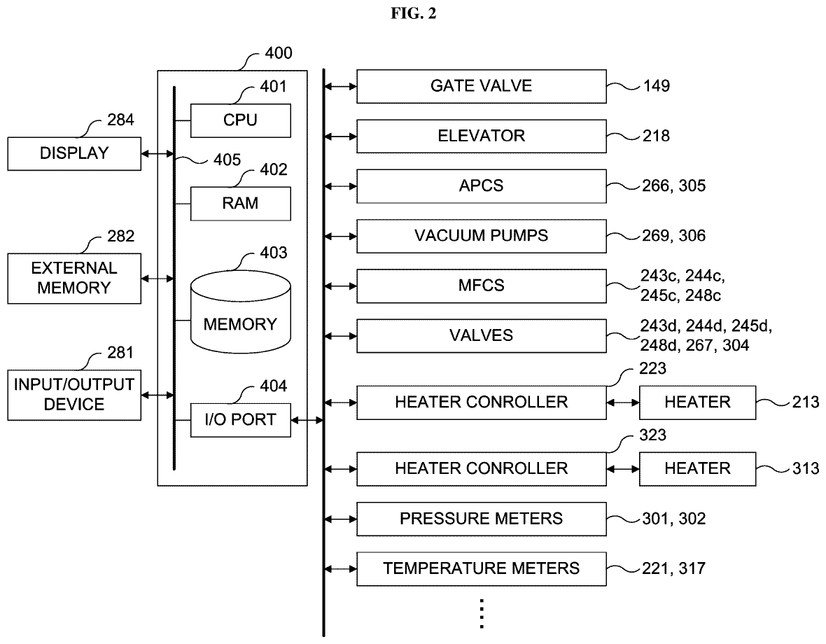

FIG. 2 is a diagram schematically illustrating a configuration of the controller 400. The controller 400 may be embodied by a computer including a CPU (Central Processing Unit) 401, a RAM (Random Access Memory) 402, a memory 403 serving as a storage and an I/O port (input/output port) 404. The RAM 402, the memory 403 and the I/O port 404 may exchange data with the CPU 401 via an internal bus 405.

The controller 400 is configured such that an input/output device 281 constituted by a component such as a keyboard and an external memory 282 are capable of being connected thereto.

A display (which is a display apparatus) 284 is configured to display data detected by each monitor (which is a monitoring apparatus). In the present embodiment, the display 284 is described as a separate component from the input/output device 281. However, the present embodiment is not limited thereto. For example, when the input/output device 281 also functions as a display screen such as a touch panel, the input/output device 281 and the display 284 may be configured as a single component.

The memory 403 may be embodied by a component such as a flash memory and an HDD (Hard Disk Drive). For example, a process recipe (also referred to as a “recipe program”) in which information such as procedures and the conditions of the substrate processing described later is stored, a control program for controlling operations of the substrate processing apparatus 100 to perform the process recipe, or a table may be readably stored in the memory 403. In addition, setting ranges of pressure values and temperature values related to the buffer space 232 described later may be stored in the memory 403. The process recipe (recipe program) is obtained by combining steps (procedures) of the substrate processing described later such that the controller 400 can execute the steps to acquire a predetermined result, and functions as a program. Hereinafter, the process recipe (recipe program) and the control program may be collectively or individually referred to simply as a “program.” Thus, in the present specification, the term “program” may refer to the process recipe (recipe program) alone, may refer to the control program alone, or may refer to both of the process recipe (recipe program) and the control program. The RAM 402 serves as a memory area (work area) in which the program or data read by the CPU 401 are temporarily stored.

The I/O port 404 is electrically connected to the components of the substrate processing apparatus 100 mentioned above such as the gate valve 149, the elevator 218, the APCs 266 and 305, the vacuum pumps 269 and 306, the MFC 243c, 244c, 245c and 248c, the valves 243d, 244d, 245d, 248d, 267 and 304, the heater controllers 223 and 323, the pressure meters 301 and 302 and the temperature meters 221 and 317.

The CPU 401 is configured to read and execute the control program from the memory 403 and read the process recipe (recipe program) in accordance with an instruction such as an operation command inputted from the input/output device 281. The CPU 401 is configured to control various operations in accordance with the recipe program such as an opening and closing operation of the gate valve 149, an elevating and lowering operation of the elevator 218, opening and closing operations of the APCs 266 and 305, on/off control operations of the vacuum pumps 269 and 306, flow rate adjusting operations of the MFCs 243c, 244c, 245c and 248c, opening and closing operations of the valves 243d, 244d, 245d, 248d, 267 and 304, a temperature control operation of the heater 213 by the heater controller 223, a temperature control operation of the heater 313 by the heater controller 323, pressure detection operations by the pressure meters 301 and 302, and temperature detection operations by the temperature meters 221 and 317.

Specifically, the controller 400 transmits control information to the heater controller 223 based on temperature information measured by the temperature meter 221. When the heater controller 223 receives the control information, the heater controller 223 controls the heater 213 with reference to the control information.

Further, the controller 400 transmits control information to the heater controller 323 based on temperature information of the buffer space 232 measured by the temperature meter 317. When the heater controller 323 receives the control information, the heater controller 323 controls the heater 313 with reference to the control information.

In addition, the controller 400 transmits control information to the heater controller 323 based on pressure information measured by the pressure meters 301 and 302. When the heater controller 323 receives the control information, the heater controller 323 controls the heater 313 with reference to the control information.

In addition, the controller 400 controls the pressure of the buffer space 232 by adjusting the opening degree of the APC 305 based on temperature information of the buffer space 232 measured by the temperature meter 317.

For example, the controller 400 according to the present embodiment may be embodied by preparing the external memory 282 (for example, a magnetic disk such as a hard disk, an optical disk such as a DVD, a magneto-optical disk such as an MO and a semiconductor memory such as a USB memory) storing the program mentioned above and installing the program onto the computer using the external memory 282. Further, a configuration capable of providing the program to the computer is not limited to the external memory 282. For example, the program may be directly provided to the computer by a communication interface such as the Internet and a dedicated line instead of the external memory 282. The memory 403 and the external memory 282 may be embodied by a non-transitory computer-readable recording medium. Hereinafter, the memory 403 and the external memory 282 may be collectively or individually referred to as a “recording medium.” Thus, in the present specification, the term “recording medium” may refer to the memory 403 alone, may refer to the external memory 282 alone, or may refer to both of the memory 403 and the external memory 282.

### (2) Substrate Processing

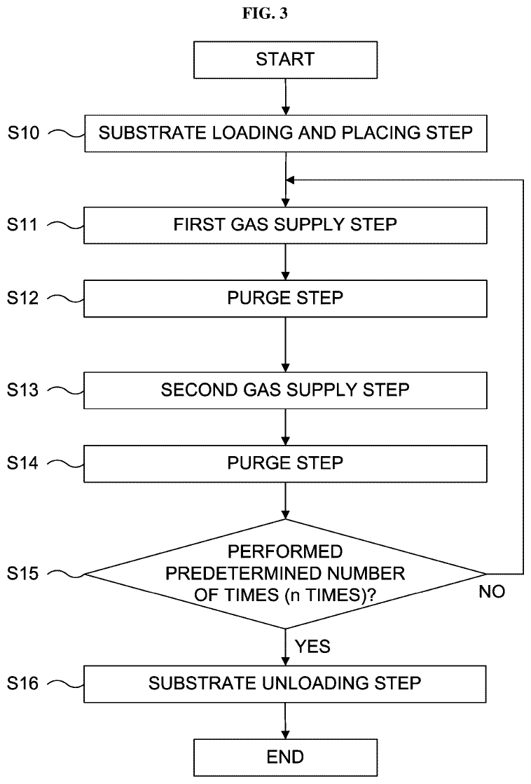

Hereinafter, as a part of a manufacturing process of a semiconductor device, a process (that is, a film forming process) of forming a film on the on the substrate S using the substrate processing apparatus 100 described above will be described with reference to FIG. 3. In the following description, the operations of the components constituting the substrate processing apparatus 100 are controlled by the controller 400.

In the present specification, the term “substrate” may refer to “a substrate itself,” or may refer to “a substrate and a stacked structure (aggregated structure) of a predetermined layer (or layers) or a film (or films) formed on a surface of the substrate.” That is, the term “substrate” may collectively refer to “a substrate and layers or films formed on a surface of the substrate.” Further, in the present specification, the term “a surface of a substrate” may refer to “a surface (exposed surface) of a substrate itself,” or may refer to “a surface of a predetermined layer or a film formed on a substrate, i.e. a top surface (uppermost surface) of the substrate as a stacked structure.”

Thus, in the present specification, the term “supplying a predetermined gas to a substrate” may refer to “directly supplying a predetermined gas to a surface (exposed surface) of a substrate itself,” or may refer to “supplying a predetermined gas to a layer or a film formed on a substrate,” that is, “supplying a predetermined gas to a top surface (uppermost surface) of a substrate as a stacked structure.” In addition, in the present specification, the term “forming a predetermined layer (or film) on a substrate” may refer to “forming a predetermined layer (or film) directly on a surface (exposed surface) of a substrate itself” or may refer to “forming a predetermined layer (or film) on a layer (or film) formed on a substrate, i.e. a top surface (uppermost surface) of the substrate as a stacked structure.”

In the present specification, the term “wafer” and the term “substrate” may be used as substantially the same meaning. In such a case, the term “substrate” in the above description may be replaced with the term “wafer.”

### Substrate Loading and Placing Step: S10

The substrate mounting table 212 is lowered to the transfer position of the substrate S such that the lift pins 207 penetrate through the through-holes 214 of the substrate mounting table 212. As a result, the lift pins 207 protrude from the surface of the substrate mounting table 212 by a predetermined height. Subsequently, the gate valve 149 is opened, and the substrate S is loaded (transferred) into the process chamber 201 by using a substrate transfer structure. Then, the substrate S is transferred onto the lift pins 207. Thereby, the substrate S is placed on and supported by the lift pins 207 (which protrude from the surface of the substrate mounting table 212) in a horizontal orientation.

After the substrate S is loaded into the vessel 202, the substrate transfer structure is retracted to a position outside the vessel 202, and the gate valve 149 is closed to hermetically seal (or close) an inside of the vessel 202. Thereafter, by elevating the substrate mounting table 212, the substrate S is placed on and supported by the substrate placing surface 211 of the substrate mounting table 212.

When the substrate S is loaded into the vessel 202, it is preferable to supply the inert gas via the third gas supplier 245 into the vessel 202 while exhausting an inner atmosphere of the vessel 202 with the first exhauster. That is, it is preferable to supply the inert gas into the vessel 202 by opening at least the valve 245d of the third gas supplier 245 in a state where the inner atmosphere of the vessel 202 is exhausted by operating the vacuum pump 269 and opening the APC 266. Thereby, it is possible to prevent (or suppress) particles from entering the vessel 202, and it is possible to prevent (or suppress) the particles from adhering onto the substrate S. In addition, the vacuum pump 269 continuously exhausts the inner atmosphere of the vessel 202 until at least the processes from the substrate loading and placing step S10 to a substrate unloading step S16 described later is completed.

When the substrate S is placed on the substrate mounting table 212, the electric power is supplied to the heater 213 provided (embedded) inside the substrate mounting table 212 such that a surface temperature of the substrate S is controlled to a predetermined temperature. When supplying the electric power to the heater 213, the temperature of the heater 213 is adjusted by controlling the state of the electric conduction to the heater 213 by the heater controller 223 based on the temperature information detected by the temperature meter 221.

Further, until at least the processes from a first gas supply step S11 to a determination step S15 described later is completed, the electric power is supplied to the heater 313 provided (embedded) inside the lid 231 such that the temperature of the buffer space 232 is controlled to be within a pre-set temperature range. When supplying the electric power to the heater 313, a temperature of the heater 313 is adjusted by controlling the state of the electric conduction to the heater 313 by the heater controller 323 mainly based on the pressure information measured by the pressure meter 302. As a result, the temperature of the buffer space 232 can be controlled to be within the pre-set temperature range.

That is, the controller 400 transmits the control information to the heater controller 323 based on the pressure information of the buffer space 232 measured by the pressure meter 302. When the heater controller 323 receives the control information, the heater controller 323 controls the heater 313 by referring to the control information. Specifically, for example, when the controller 400 determines that the pressure value of the buffer space 232 measured by the pressure meter 302 is out of a pre-set pressure range, the heater controller 323 controls the heater 313 to adjust the temperature of the buffer space 232. More specifically, for example, when the controller 400 determines that the pressure value of the buffer space 232 measured by the pressure meter 302 is below the pre-set pressure range, the heater controller 323 controls the heater 313 to increase the temperature of the buffer space 232. In other words, the controller 400 causes the heater controller 323 to control the heater 313 to adjust the temperature of the buffer space 232 measured by the temperature meter 317 such that the pressure of the buffer space 232 is within the pre-set pressure range. When the heater controller 323 controls the heater 313, at least the temperature of the buffer space 232 during the substrate processing being performed is adjusted to be higher than a temperature at which the gas is liquefied and lower than a process temperature of the substrate S. Thereby, it is possible to suppress the liquefaction of the gas while suppressing a thermal decomposition of the gas supplied to the buffer space 232 as compared with a case where the substrate processing is performed. As a result, it is possible to prevent the particles from being generated. In the present specification, the term “process temperature” may refer to a temperature of the substrate S or may refer to an inner temperature of the process chamber 201, and the term “process pressure” may refer to an inner pressure of the process chamber 201. In addition, the term “process time” may refer to a time duration of continuously performing a process related thereto. The same also applies to the following description.

That is, the temperature of the buffer space 232 is controlled such that the pressure of the buffer space 232 is adjusted to maintain the pressure of the buffer space 232 within a pressure range in which the gas is not liquefied. By preventing a temperature of the gas from decreasing in the buffer space 232 in a manner described above, it is possible to prevent the gas supplied through a supply pipe from re-liquefying in the buffer space 232. As a result, it is possible to stabilize an amount of the gas supplied to the process chamber 201, and it is also possible to improve the process reproducibility. In addition, by suppressing the liquefaction in the shower head 230 in a manner described above, it is possible to prevent the particles from being generated in the shower head 230.

When the temperature value of the buffer space 232 measured by the temperature meter 317 is out of a pre-set temperature range, the controller 400 may control the heater 313 via the heater controller 323 to adjust the temperature of the buffer space 232. More specifically, for example, when the controller 400 determines that the temperature value of the buffer space 232 measured by the temperature meter 317 is below the pre-set temperature range, the heater controller 323 controls the heater 313 to increase the temperature of the buffer space 232. When the heater controller 323 controls the heater 313, the temperature of the buffer space 232 may be adjusted to be higher than the temperature at which the gas is liquefied and lower than the process temperature of the substrate S.

### First Gas Supply Step: S11

After the substrate mounting table 212 is moved to the substrate processing position, an inner atmosphere of the process chamber 201 is exhausted through the exhaust pipe 262 to adjust the inner pressure of the process chamber 201.

While adjusting the inner pressure of the process chamber 201 to the predetermined pressure, the valve 234d is opened to supply the first gas into the process space 205 through the common gas supply pipe 242 and the shower head 230 when the temperature of the buffer space 232 and the temperature of the substrate S reach predetermined temperatures, respectively. In the present step, the MFC 243c is adjusted such that the flow rate of the first gas is adjusted to a predetermined flow rate. In the present step, the inner atmosphere of the process space 205 is exhausted through the exhaust pipe 262. Further, in the present step, the valve 245d is opened to supply the inert gas through the third gas supply pipe 245a. Thereby, it is possible to prevent the first gas from entering the third gas supplier 245. By supplying the first gas, a first layer is formed on the substrate S. After a predetermined time has elapsed from a supply of the first gas, the valve 243d is closed so as to stop the supply of the first gas.

### Purge Step: S12

Thereafter, the inert gas is supplied through the third gas supply pipe 245a to purge the process space 205. As a result, the first gas that is not bonded to the substrate S in the first gas supply step S11 is removed from the process space 205 through the exhaust pipe 262.

### Second Gas Supply Step: S13

Subsequently, the valve 244d is opened to supply the second gas into the process space 205 via the plasma generator (that is, the remote plasma unit) 244e, the common gas supply pipe 242 and the shower head 230. In the present step, the MFC 244c is adjusted such that a flow rate of the second gas is adjusted to a predetermined flow rate. Further, also in the present step, the valve 245d is opened to supply the inert gas through the third gas supply pipe 245a. Thereby, it is possible to prevent the second gas from entering the third gas supplier 245.

The second gas converted into the plasma state by the plasma generator 244e is supplied into the process space 205 through the common gas supply pipe 242 and the shower head 230. The second gas supplied into the process space 205 reacts with the first layer on the substrate S. Thereby, the first layer formed on the substrate S is modified by the plasma of the second gas. As a result, a second layer is formed on the substrate S.

After a predetermined time has elapsed from a supply of the second gas, the valve 244d is closed to stop the supply of the second gas.

### Purge Step: S14

Thereafter, the purge step S14 similar to the purge step S12 described above is performed.

### Determination Step: S15

In the present step, it is determined whether or not a cycle including the first gas supply step S11, the purge step S12, the second gas supply step S13 and the purge step S14 is performed a predetermined number of times (n times, where n is an integer of 1 or more). By performing the cycle the predetermined number of times, a film of a desired thickness is formed on the substrate S.

### Substrate Unloading Step: S16

Subsequently, the substrate mounting table 212 is lowered until the substrate S is placed on the lift pins 207 protruding from the surface of the substrate mounting table 212. Then, the gate valve 149 is opened, and the substrate S is transferred (unloaded) out of the vessel 202 by using the substrate transfer structure (not shown). Thereafter, when the substrate processing is to be terminated, a supply of the inert gas through the third gas supplier 245 into the vessel 202 is stopped.

### Second Embodiment

Subsequently, a second embodiment according to the technique of the present disclosure will be described. In the second embodiment, the liquefaction of the gas in the buffer space 232 is suppressed mainly by using the temperature information of the buffer space 232. That is, in the second embodiment, the pressure of the buffer space 232 is adjusted such that the temperature of the buffer space 232 is within a temperature range in which the gas is not liquefied until at least the processes from the first gas supply step S11 to the determination step S15 described above is completed. Hereinafter, portions of the second embodiment different from those of the first embodiment will be described in detail below, and the description of portions the same as the first embodiment will be omitted.

In the second embodiment, until at least the processes from the first gas supply step S11 to the determination step S15 described above is completed, the controller 400 is configured to adjust the pressure of the buffer space 232 by the APC 305 when the temperature of the buffer space 232 measured by the temperature meter 317 is out of the pre-set temperature range.

Specifically, the controller 400 detects the temperature of the buffer space 232 by the temperature meter 317. The controller 400 is configured to be capable of adjusting the pressure of the buffer space 232 by the APC 305 when the temperature of the buffer space 232 is out of the pre-set temperature range. More specifically, for example, when the controller 400 determines that the temperature of the buffer space 232 measured by the temperature meter 317 is below the pre-set temperature range, the controller 400 increases the pressure of the buffer space 232 by the APC 305. In other words, the APC 305 adjusts the pressure of the buffer space 232 measured by the pressure meter 302 such that the temperature of the buffer space 232 is within the pre-set temperature range. Thereby, it is possible to suppress the liquefaction of the gas supplied to the buffer space 232. When the APC 305 adjusts the pressure of the buffer space 232, at least the temperature of the buffer space 232 during the substrate processing being performed, is adjusted to be higher than the temperature at which the gas is liquefied and lower than the process temperature of the substrate S. According to the present embodiment, it is possible to obtain substantially the same effects as those of the embodiment described above.

### Third Embodiment

Subsequently, a third embodiment according to the technique of the present disclosure will be described. In the third embodiment, the liquefaction of the gas in the buffer space 232 is suppressed mainly by using pressure information inside and outside the buffer space 232. That is, in the third embodiment, the temperature of the buffer space 232 is adjusted such that a pressure difference between the inside and the outside of the buffer space 232 (the buffer chamber 232a) is within a pre-set range in which the gas is not liquefied until at least the processes from the first gas supply step S11 to the determination step S15 described above is completed.

In the third embodiment, until at least the processes from the first gas supply step S11 to the determination step S15 described above is completed, the controller 400 is configured to detect the pressure difference between the inside and the outside of the buffer space 232 by the pressure meter 301 and the pressure meter 302. That is, the controller 400 calculates the pressure difference between the inside and the outside of the buffer space 232, which is a difference between the pressure value in the common gas supply pipe 242 measured by the pressure meter 301 and the pressure value in the buffer space 232 measured by the pressure meter 302. Then, the controller 400 is configured to adjust the temperature of the buffer space 232 by controlling the heater 313 using the heater controller 323 when the pressure difference between the inside and the outside of the buffer space 232 is out of the pre-set range.

More specifically, for example, when the controller 400 determines that the difference between the pressure value in the common gas supply pipe 242 measured by the pressure meter 301 and the pressure value in the buffer space 232 measured by the pressure meter 302 is above the pre-set range, the controller 400 controls the heater 313 using the heater controller 323 to increase the temperature of the buffer space 232. When the controller 400 controls the heater 313, at least the temperature of the buffer space 232 during the substrate processing being performed is adjusted to be higher than the temperature at which the gas is liquefied and lower than the process temperature of the substrate S. According to the present embodiment, it is possible to obtain substantially the same effects as those of the embodiment described above.

### Other Embodiments of Present Disclosure

While the technique of the present disclosure is described in detail by way of the embodiments mentioned above, the technique of the present disclosure is not limited thereto. The technique of the present disclosure may be modified in various ways without departing from the scope thereof.

For example, the embodiments mentioned above are described by way of an example in which the heater 313 configured to heat the buffer space 232 is provided at the lid 231. However, the technique of the present disclosure is not limited thereto. For example, the technique of the present disclosure may also be applied when the heater 313 is provided at the gas guide 270.

For example, the above embodiments mentioned above are described by way of an example in which the film forming process is performed as the substrate processing performed by the substrate processing apparatus 100. However, the technique of the present disclosure is not limited thereto. That is, the technique of the present disclosure can be applied not only to the film forming process of forming the film exemplified in the embodiments but also to a film-forming process of forming another film. For example, the specific contents of the film forming process are not limited to those exemplified in the embodiments mentioned above. For example, in addition to or instead of the film forming process mentioned above, the technique of the present disclosure may be applied to a process such as an annealing process, a diffusion process, an oxidation process, a nitridation process and a lithography process. The technique of the present disclosure may also be applied to other substrate processing apparatuses such as an annealing apparatus, an etching apparatus, an oxidation apparatus, a nitridation apparatus, an exposure apparatus, a coating apparatus, a drying apparatus, a heating apparatus, an apparatus using the plasma and combinations thereof. The technique of the present disclosure may also be applied when a constituent of one of the embodiments mentioned above is substituted with another constituent of another embodiment, or when a constituent of one of the embodiments mentioned above is added to another embodiment. The technique of the present disclosure may also be applied when the constituent of the embodiments mentioned above is omitted or substituted, or when a constituent added to the embodiments mentioned above.

For example, it is preferable that recipes (process recipes) used in processes are prepared individually in accordance with the contents of the processes and stored in the memory 403 via an electric communication line or the external memory 282. When starting each process, it is preferable that the CPU 401 selects an appropriate recipe among the recipes stored in the memory 403 in accordance with the contents of each process. Thus, various films of different composition ratios, qualities and thicknesses can be formed in a reliably reproducible manner by using a single substrate processing apparatus (that is, the substrate processing apparatus 100 described above). In addition, since a burden on an operating personnel in charge of the substrate processing apparatus can be reduced, various processes can be performed quickly while avoiding an error in operating the substrate processing apparatus.

The recipe described above is not limited to creating a new recipe. For example, the recipe may be prepared by changing an existing recipe stored (or installed) in the substrate processing apparatus 100 in advance. When changing the existing recipe to a new recipe, the new recipe may be installed in the substrate processing apparatus 100 via the electric communication line or a recording medium in which the new recipe is stored. Further, the existing recipe already stored in the substrate processing apparatus 100 may be directly changed to the new recipe by operating the input/output device 281 of the substrate processing apparatus 100.

Further, the embodiments described above may be appropriately combined. The process procedures and the process conditions of each combination thereof may be substantially the same as those of the embodiments described above.

According to some embodiments of the present disclosure, it is possible to suppress the change in the state of the gas.

What is claimed is:

1. A substrate processing method comprising:
(a) adjusting at least one selected from the group of a pressure and a temperature of a buffer space in a buffer chamber when the temperature of the buffer space is out of a pre-set temperature range or the pressure of the buffer space is out of a pre-set pressure range; and
(b) processing a substrate by supplying a gas via the buffer chamber to a process chamber in which the substrate is processed.

2. The substrate processing method of claim 1, wherein, in (a), when the temperature of the buffer space is out of the pre-set temperature range, the pressure of the buffer space is adjusted.

3. The substrate processing method of claim 2, wherein, in (a), when the pressure of the buffer space is out of the pre-set pressure range, the temperature of the buffer space is adjusted.

4. The substrate processing method of claim 1, wherein, in (a), when the pressure of the buffer space is out of the pre-set pressure range, the temperature of the buffer space is adjusted.

5. The substrate processing method of claim 1, wherein, in (a), when the temperature of the buffer space is below the pre-set temperature range, the pressure of the buffer space is increased.

6. The substrate processing method of claim 1, wherein, in (a), when the pressure of the buffer space is below the pre-set pressure range, the temperature of the buffer space is increased.

7. The substrate processing method of claim 1, wherein (b) is performed after (a).

8. The substrate processing method of claim 1, wherein (b) comprises:
(b-1) supplying a first gas to the process chamber; and
(b-2) supplying a second gas to the process chamber,
wherein (a) is performed in parallel with performing at least one of (b-1) or (b-2).

9. The substrate processing method of claim 1, wherein, at least in (b), the temperature of the buffer space is set to be lower than a process temperature of the substrate.

10. The substrate processing method of claim 1, wherein, in (a), the temperature of the buffer space is adjusted to maintain the pressure of the buffer space within a pressure range in which the gas is not liquefied.

11. The substrate processing method of claim 1, wherein, in (b), the temperature of the buffer space is set to a temperature at which it is possible to suppress a liquefaction of the gas and a thermal decomposition of the gas on the substrate.

12. The substrate processing method of claim 1, wherein, in (a), a pressure difference between an inside and an outside of the buffer chamber is detected, and the temperature of the buffer space is adjusted when the pressure difference is out of a pre-set range.

13. The substrate processing method of claim 1, wherein, in (a), the temperature of the buffer space is adjusted when a difference between the pressure of the buffer space and an inner pressure of a gas supplier is out of a pre-set range, the gas supplier being in communication with the buffer chamber and the gas being supplied into the buffer chamber through the gas supplier.

14. The substrate processing method of claim 13, wherein the gas supplier is provided with a gas supply pipe in communication with the buffer space, and
wherein the inner pressure of the gas supplier is an inner pressure of the gas supply pipe.

15. A method of manufacturing a semiconductor device, comprising:
the substrate processing method of claim 1.

16. A non-transitory computer-readable recording medium storing a program that causes a substrate processing apparatus, by a computer, to perform:
(a) adjusting at least one selected from the group of a pressure and a temperature of a buffer space in a buffer chamber when the temperature of the buffer space is out of a pre-set temperature range or the pressure of the buffer space is out of a pre-set pressure range; and
(b) processing a substrate by supplying a gas via the buffer chamber to a process chamber in which the substrate is processed.

17. A substrate processing apparatus comprising:
a buffer chamber provided with a buffer space;
a gas supplier configured to supply a gas to a process chamber via the buffer chamber;
a heater configured to heat the buffer space; and
a controller configured to be capable of performing:
(a) adjusting at least one selected from the group of a pressure and a temperature of the buffer space in the buffer chamber when the temperature of the buffer space is out of a pre-set temperature range or the pressure of the buffer space is out of a pre-set pressure range; and
(b) processing a substrate by supplying the gas via the buffer chamber to the process chamber in which the substrate is processed.
